(19) United States
(12) Patent Application Publication
(10) Pub. No.: US 2012/0247543 A1
(43) Pub. Date: Oct. 4, 2012

(54) Photovoltaic Structure

(75) Inventor: Sharone Zehavi, San Jose, CA (US)

(73) Assignee: Integrated Photovoltaic, Inc., San Jose, CA (US)

(21) Appl. No.: 13/077,870

(22) Filed: Mar. 31, 2011

(51) Int. Cl. H01L 31/06

(52) U.S. Cl. 136/255

(57) ABSTRACT

A photovoltaic device on a low-cost, conductive silicon layer is disclosed. The device comprises two semiconductor layers forming an active region; optional layers include “heterojunction layers”, one or more barrier layers, a cap layer, a conductive and/or metallization layer, an anti-reflection layer, and distributed Bragg reflector. The device may comprise multiple active regions.

### CROSS-REFERENCE TO RELATED APPLICATIONS

This application is related in part to U.S. application Ser. Nos. 12/074,651, 12/720,153, 12/749,160, 12/789,357, 12/860,048, 12/950,725, 12/860,088, 13/010,700, 13/019,965, 13/073,884, and U.S. Pat. No. 7,789,331, all owned by the same assignee and all incorporated by reference in their entirety herein. Additional technical explanation and background is cited in the referenced material.

### BACKGROUND OF THE INVENTION

1. Field of the Invention

The invention relates generally to a device for converting radiation to electrical energy comprising an active region and one or more heterojunctions.

2. Description of Related Art

Prior art in this area includes U.S. Pat. No. 5,403,771; U.S. Pat. No. 7,807,495; U.S. Pat. No. 7,781,669; U.S.2008/0261347, U.S.2010/0229927, U.S.2010/0236613, U.S.2010/00300507, U.S.2011/024793, and U.S.2011/0068367. FIGS. 1 and 2 are from U.S.2008/0261347 assigned to Sanyo disclosing a single and double heterojunction solar cell structure formed by catalytic wire induced deposition. An amorphous, hydrogenated silicon carbide layer is deposited on a tin oxide electrode layer in FIG. 1; FIG. 2 discloses a double heterojunction structure with amorphous silicon layers. Yuan, et al. in 33^{rd} IEEE Photovoltaic Specialists Conference, 2008, NREL/CP-520-42566, May 2008, and Wang in Applied Physics Letters, 96, 013507 (2010), disclose the structure of FIG. 3 with a single intrinsic, hydrogenated, amorphous silicon layer is in contact with a thick, single crystal n-type silicon layer. Kleider, et al. in “Characterization of silicon heterojunctions for solar cells”; Nanoscale research Letters 2011, 6, 152, disclose a heterojunction structure as shown in FIG. 4 similar to the Sanyo structure of FIG. 2. Preceding patents and literature cited are incorporated in their entirety herein by reference. None of the cited prior art effectively addresses the primary issue for solar cells, namely low manufacturing cost in order to achieve commercial level conversion efficiency. A key factor in the instant invention, as noted in the literature, is that a need for high bulk lifetime is relaxed in thinner layers because of the square root dependence of diffusion length on lifetime; when thickness of an active region is reduced by half, bulk lifetime can be reduced by a factor of four without sacrificing efficiency.

### BRIEF SUMMARY OF THE INVENTION

A photovoltaic device with multiple layers is disclosed. The device comprises one or more semiconductor layers forming an active region; a layer underlying the semiconductor layers is formed of a low cost material; optionally, silicon; optionally silicon carbide; one or more layers form heterojunctions with the active region; optional layers include one or more barrier layers, a cap layer, a conductive layer, an anti-reflection layer, and distributed Bragg reflector. Optionally, a device comprises multiple active regions.

In one embodiment the invention discloses deposition of a layer of doped semiconductor onto a conductive layer; optionally, silicon; optionally a silicon-carbon mixture or compound. Should a conductive layer contain contaminants that can diffuse into active semiconductor layers, or when a conductive layer, optionally, functioning as a substrate, can create a junction with active semiconductor layers reducing the efficiency of an intended device by promoting recombination, the conductive layer may be coated with a, optionally non-conducting, barrier layer. In one embodiment, a non-contaminating and non-recombining interface is created with a barrier layer comprising an array of vias, enabling effective collection of a photocurrent.

### BRIEF DESCRIPTION OF THE SEVERAL VIEWS OF THE DRAWINGS

FIG. 1 is prior art from Sanyo.

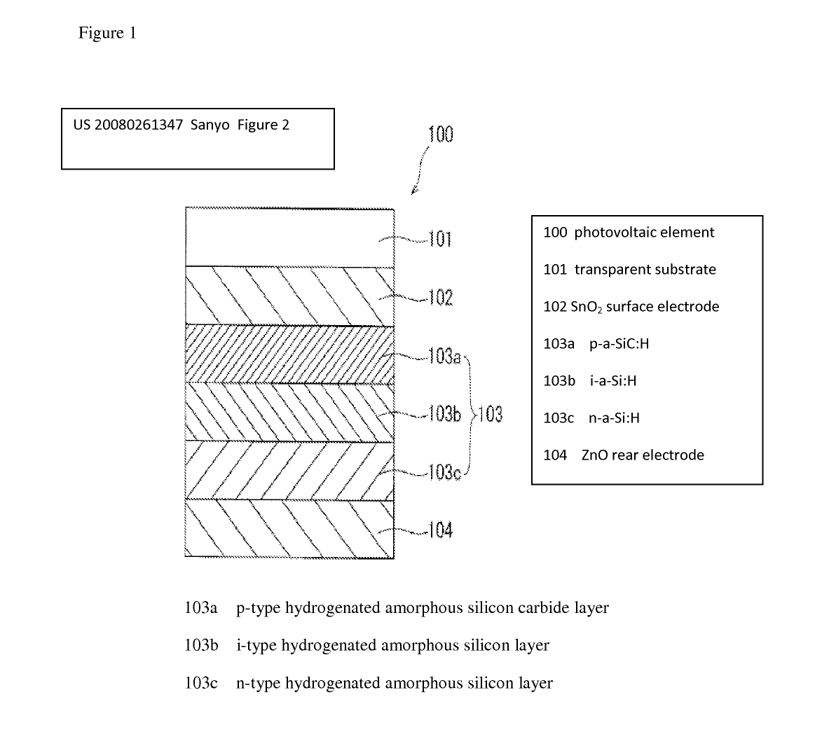

FIG. 2 is prior art from Sanyo.

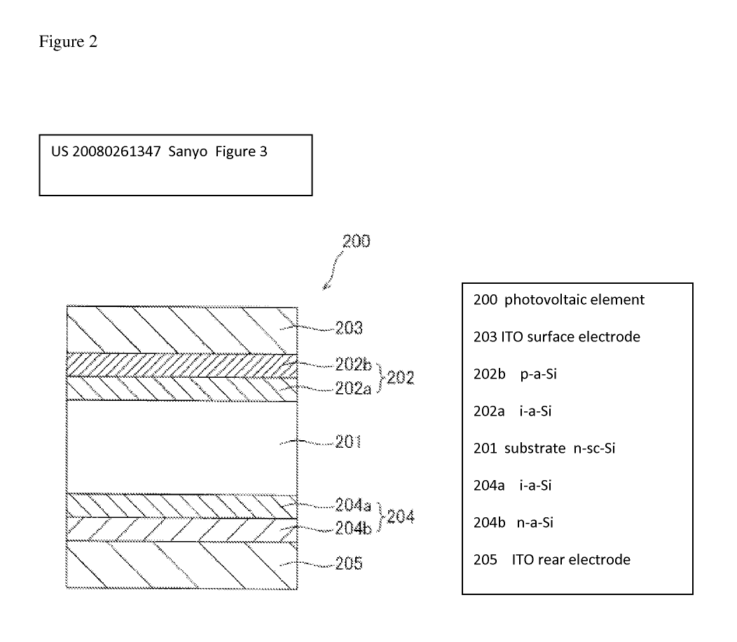

FIG. 3 is prior art from NREL.

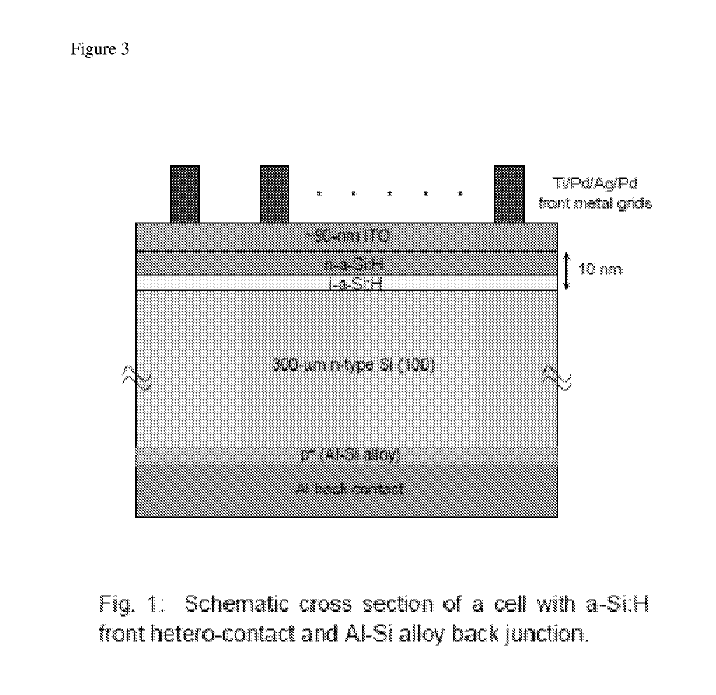

FIG. 4 is prior art from the literature.

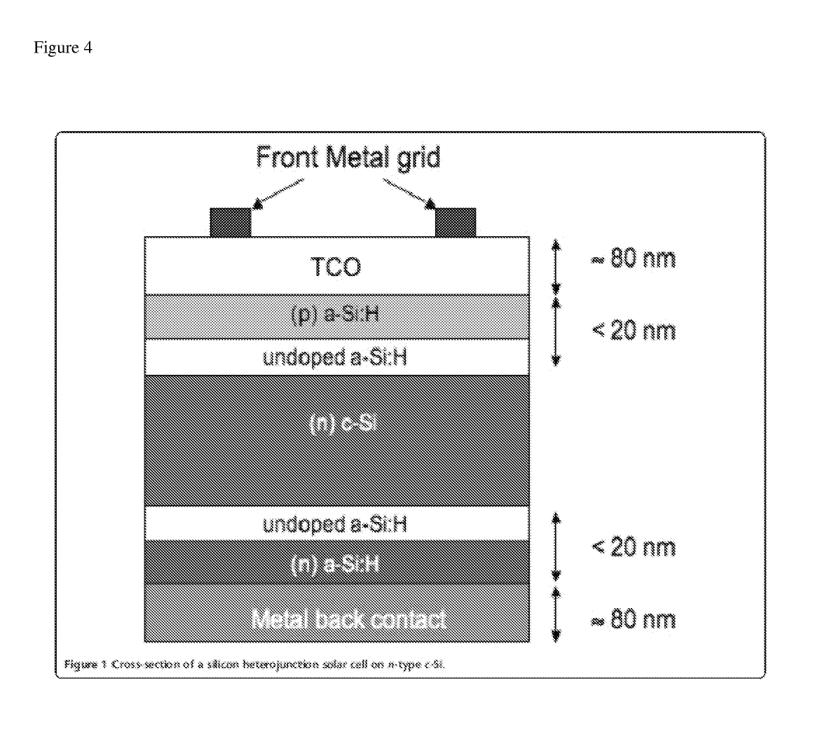

FIG. 5 is a schematic drawing of several embodiments of the instant invention.

FIG. 6 is a schematic drawing of several embodiments of the instant invention.

### DETAILED DESCRIPTION OF THE INVENTION

The generation of high temperature plasma, associated deposition techniques and various post processing steps are done by techniques disclosed in U.S. Ser. No. 12/074,651 and references cited in Related Applications and prior art; optional steps include selective recrystallization of various layers and deposition of porous layers. Optionally, the semiconductor layers comprise Group IV, III-V or II-VI semiconductors. Some embodiments comprise deposition by high-purity plasma spray of one or more layers of a photovoltaic device.

In some embodiments a photovoltaic device operable to convert incident radiation into electrical energy comprises a first semiconductor layer of a first conductivity type, a second semiconductor layer of a second conductivity type on the first semiconductor layer; wherein the first or second semiconductor layer is formed by a high-purity plasma spray; and wherein the interface between the first semiconductor layer and the second semiconductor layer forms an active region operable to convert incident radiation into electrical energy; optionally, a reflective layer comprises a plurality of layers of a composition chosen from a group consisting of SiO₂, Al₂O₃, TaN, TiO₂, SiC, metal oxides, metal carbides, metal nitrides, SixNy, and porous materials such that a first portion of the plurality of layers is operable as a distributed Bragg reflector and a second portion of the plurality of layers is conductive.

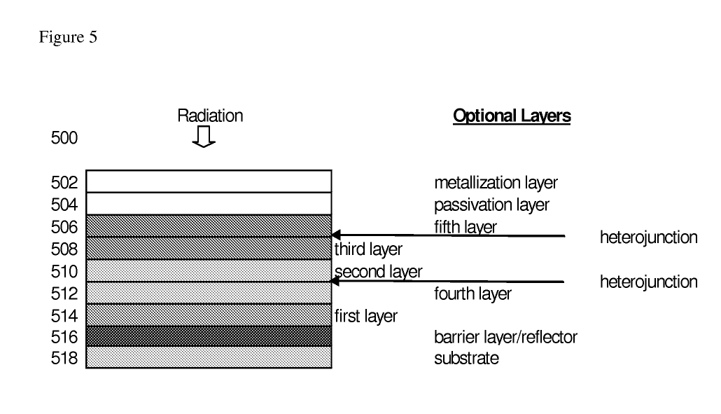

As shown schematically in FIG. 5, in some embodiments a photovoltaic device 500 for converting incident radiation to electrical energy comprises a first layer 514 comprising silicon such that minority carrier lifetime is less than 1 μs and the layer thickness, optionally including a substrate layer 518, is about 50 microns or greater; a second layer 510 of first conductivity type is adjacent the first layer comprising a semiconductor such that minority carrier lifetime is greater than 100 nanoseconds and the layer thickness is about 10 microns or less; a third layer 508 of second conductivity type is in contact with the second layer comprising a semiconductor such that minority carrier lifetime is greater than 100 nanoseconds and wherein the second and third layers are operable as an active region such that a portion of incident radiation is converted to electrical energy; optionally, a device 500 further comprises a barrier layer 516 between substrate layer 518 and first layer 514; alternatively, barrier layer 520 is between the first conductive layer 512 and the second layer 510; optionally, a device is formed by one or more processes chosen from a group consisting of physical vapor deposition, chemical vapor deposition, plasma-enhanced chemical vapor deposition, molten application and plasma spraying; optionally, a device of further comprises a fourth layer 512 between the first conductive layer 514 and the second layer 510 comprising a first heterojunction material region in contact with the second layer such that a heterojunction is formed between the first heterojunction material region and the second layer; optionally, a device further comprises fifth layer 506 in contact with the third layer 508 comprising a second heterojunction material region such that a heterojunction is formed between the second heterojunction material region and the third layer; optionally, the fourth layer and the fifth layer are of a composition chosen from a group consisting of Group IV elements, hydrogen, silicon carbide, amorphous silicon, nano-crystalline silicon, metallic nitrides, metallic carbides and mixtures thereof; optionally, a device further comprises a substrate 518 adjacent the first conductive layer such that the first conductive layer separates the substrate from the second layer; optionally, the substrate is chosen from a group consisting of graphite, graphite foil, glassy graphite, impregnated graphite, pyrolytic carbon, pyrolytic carbon coated graphite, flexible foil coated with graphite, graphite powder, carbon paper, carbon cloth, carbon, glass, alumina, carbon nanotube coated substrates, carbide coated substrates, graphene coated substrates, silicon-carbon composite, silicon carbide, and mixtures thereof; optionally, the composition of the first conductive layer is chosen from a group consisting of silicon, SiC, conductive metal nitride, aluminum, copper, silver, transparent metal alloy and transparent conductive metal oxide and combinations thereof; optionally, a barrier layer 516 comprises one or more layers of a composition chosen from a group consisting of Si, SiO₂, A₁₂O₃, TaN, TiO₂, silicon carbides, silicon nitrides, metal oxides, metal carbides, metal nitrides and conductive ceramics; optionally, the first conductive layer is formed by deposition from a molten source dispensed directly onto a platen; optionally, a device wherein the platen is a substrate 518; optionally, a device wherein the second and third layers comprise Group IV, Group III-V or Group II-VI semiconductors. In some embodiments, one or more of the first, second, third, fourth and fifth layers are formed by plasma spraying and one or more of the layers are recrystallized by an optical source such as a laser or flash lamp or other means for heating the layers. In some embodiments the first, second, third, fourth and fifth layers are polycrystalline with a grain size in the lateral dimension at least two to ten times the layer thickness.

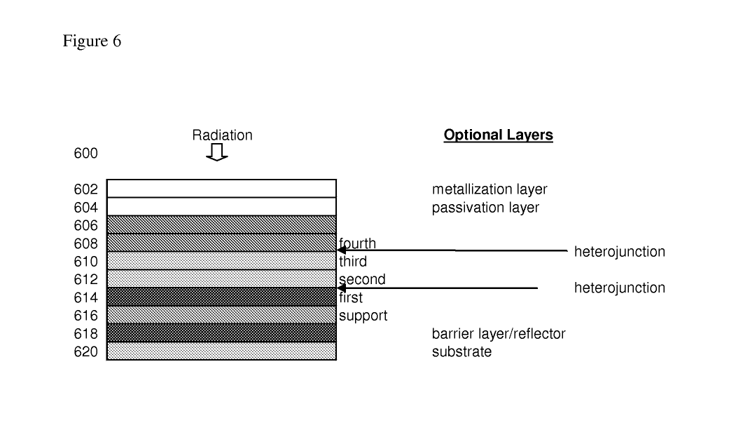

In some embodiments, schematically shown in FIG. 6, a photovoltaic device 600 operable to convert incident radiation into electrical energy comprises a first support layer 616 comprising silicon with a resistivity less than 10 ohm-cm; a first semiconductor layer 614 of a first conductivity type above the first support layer; a second semiconductor layer 612 of a first conductivity type in contact with the first semiconductor layer of a first conductivity type layer; a third semiconductor layer 610 of a second conductivity type in contact with the second semiconductor layer of a first conductivity type layer; and a fourth semiconductor layer 608 of a second conductivity type in contact with the third semiconductor layer of a second conductivity type layer; wherein the interface between the second semiconductor layer and the third semiconductor layer forms an active region operable to convert incident radiation into electrical energy and the interface between the first semiconductor layer and the second semiconductor layer forms a first heterojunction and the interface between the third semiconductor layer and the fourth semiconductor layer forms a second heterojunction; optionally, the second and third semiconductor layers consist of one or more Group IV elements; optionally, the first and fourth semiconductor layers consist of one or more Group IV elements. Optionally, a barrier layer may be between support layer 616 and first layer 614, not shown. In some embodiments, one or more of the first, second, third, fourth and support layers are formed by plasma spraying and one or more of the layers are recrystallized by an optical source such as a laser or flash lamp or other means for heating the layers. In some embodiments the first, second, third, fourth and support layers are polycrystalline with a grain size in the lateral dimension at least two to ten times the layer thickness.

Metallization layers 502 and 602 may be transparent conductive oxides; passivation layers 504 and 604 may be transparent non-conductive oxides. Substrate layer 620 may be of similar composition as substrate 518; barrier and reflector layers 520, 516, 618 may be of similar composition. Layers 608 and 614 are of a composition chosen from a group consisting of Group IV elements, hydrogen, silicon carbide, amorphous silicon, nano-crystalline silicon, metallic nitrides, metallic carbides and mixtures thereof.

It will be understood that when an element as a layer, region or substrate is referred to as being “on” or “over” or “adjacent” another element, it can be directly on the other element or intervening elements may also be present. In contrast, when an element is referred to as being “directly on” or “directly over” or “in contact with” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein, “transparent barrier layer” or “transparent” or “reflective” in general applies to at least some portion of the solar spectrum; a “transparent layer” or “reflective layer” need not be transparent or reflective to the entire solar spectra; rather transparent or reflective to a portion of the spectra qualifies as transparent and reflective.

The foregoing described embodiments of the invention are provided as illustrations and descriptions. They are not intended to limit the invention to a precise form as described. In particular, it is contemplated that functional implementation of invention described herein may be implemented equivalently in various combinations or other functional components or building blocks. Other variations and embodiments are possible in light of above teachings to one knowledgeable in the art of semiconductors, thin film deposition techniques, and materials; it is thus intended that the scope of invention not be limited by this Detailed Description, but rather by Claims following. All patents, patent applications, and other documents referenced herein are incorporated by reference herein in their entirety for all purposes.

In the preceding description, numerous specific details are set forth, such as particular structures, components, materials, dimensions, processing steps and techniques, in order to provide a thorough understanding of the present invention. However, it will be appreciated by one of ordinary skill in the art that the invention may be practiced without these specific details. In other instances, well-known structures or processing steps have not been described in detail in order to avoid obscuring the invention.

I claim:

1. A photovoltaic device for converting incident radiation to electrical energy comprising:
a first layer comprising silicon such that minority carrier lifetime is less than 1 μs and the layer thickness is about 50 microns or greater;
a second layer of first conductivity type adjacent the first layer comprising a semiconductor such that minority carrier lifetime is greater than 100 nanoseconds and the layer thickness is about 10 microns or less;
a third layer of second conductivity type in contact with the second layer comprising a semiconductor such that minority carrier lifetime is greater than 100 nanoseconds and wherein the second and third layers are operable as an active region such that a portion of incident radiation is converted to electrical energy.

2. The device of claim 1 further comprising a barrier layer between the first conductive layer and the second layer.

3. The device of claim 1 wherein the device is formed by one or more processes chosen from a group consisting of physical vapor deposition, chemical vapor deposition, plasma-enhanced chemical vapor deposition, molten application and plasma spraying.

4. The device of claim 1 further comprising a fourth layer between the first conductive layer and the second layer comprising a first heterojunction material region in contact with the second layer such that a heterojunction is formed between the first heterojunction material region and the second layer.

5. The device of claim 4 wherein the first, second, third and fourth layers are formed by plasma spraying.

6. The device of claim 1 further comprising fifth layer in contact with the third layer comprising a second heterojunction material region such that a heterojunction is formed between the lightly doped second conductivity type region and the third layer.

7. The device of claim 4 wherein the fourth layer is of a composition chosen from a group consisting of Group IV elements, hydrogen, silicon carbide, amorphous silicon, nano-crystalline silicon, metallic nitrides, metallic carbides and mixtures thereof.

8. The device of claim 6 wherein the fifth layer is of a composition chosen from a group consisting of Group IV elements, hydrogen, silicon carbide, amorphous silicon, nano-crystalline silicon, metallic nitrides, metallic carbides and mixtures thereof.

9. The device of claim 1 further comprising a substrate adjacent the first conductive layer such that the first conductive layer separates the substrate from the second layer.

10. The device of claim 9 wherein the substrate is chosen from a group consisting of graphite, graphite foil, glassy graphite, impregnated graphite, pyrolytic carbon, pyrolytic carbon coated graphite, flexible foil coated with graphite, graphite powder, carbon paper, carbon cloth, carbon, glass, alumina, carbon nanotube coated substrates, carbide coated substrates, graphene coated substrates, silicon-carbon composite, silicon carbide, and mixtures thereof.

11. The device of claim 1 wherein the composition of the first conductive layer is chosen from a group consisting of silicon, SiC, conductive metal nitride, aluminum, copper, silver, transparent metal alloy and transparent conductive metal oxide and combinations thereof.

12. The device of claim 2 wherein the barrier layer comprises one or more layers of a composition chosen from a group consisting of Si, SiO2, Al2O3, TaN, TiO2, silicon carbides, silicon nitrides, metal oxides, metal carbides, metal nitrides and conductive ceramics.

13. The device of claim 1 wherein the first conductive layer is formed by deposition from a molten source dispensed directly onto a platen.

14. The device of claim 13 wherein the platen is a substrate.

15. The device of claim 1 wherein the second and third layers comprise Group IV, Group III-V or Group II-VI semiconductors.

16. A photovoltaic device operable to convert incident radiation into electrical energy comprising:
a first support layer of comprising silicon with a resistivity less than 10 ohm-cm;
a first semiconductor layer of a first conductivity type above the first support layer;
a second semiconductor layer of a first conductivity type in contact with the first semiconductor layer of a first conductivity type layer;
a third semiconductor layer of a second conductivity type in contact with the second semiconductor layer of a first conductivity type layer; and
a fourth semiconductor layer of a second conductivity type in contact with the third semiconductor layer of a second conductivity type layer;
wherein the interface between the second semiconductor layer and the third semiconductor layer forms an active region operable to convert incident radiation into electrical energy and the interface between the first semiconductor layer and the second semiconductor layer forms a first heterojunction and the interface between the third semiconductor layer and the fourth semiconductor layer forms a second heterojunction.

17. The device of claim 16 wherein the second and third semiconductor layers consist of one or more Group IV elements.

18. The device of claim 16 wherein the first and fourth semiconductor layers consist of one or more Group IV elements.

19. The device of claim 16 wherein at least one of the support, first, second, third and fourth layers are formed by plasma spraying.
